(19) United States
(12) Patent Application Publication
(10) Pub. No.: US 2023/0209904 A1
(43) Pub. Date: Jun. 29, 2023

(54) DISPLAY APPARATUS

(71) Applicant: LG DISPLAY CO., LTD., SEOUL (KR)

(72) Inventors: Joonsuk LEE, Paju-si (KR); SeJune KIM, Paju-si (KR); DoYoung KUM, Paju-si (KR)

(73) Assignee: LG DISPLAY CO., LTD., SEOUL (KR)

(21) Appl. No.: 17/976,772

(22) Filed: Oct. 29, 2022

(30) Foreign Application Priority Data
Dec. 27, 2021 (KR) 10-2021-0188250

(51) Int. Cl. H10K 59/122; H10K 59/80

(52) U.S. Cl. CPC H10K 59/122; H10K 59/8792

(57) ABSTRACT

A display apparatus includes a substrate including a light emission area and a non-light emission area surrounding the light emission area, a circuit element layer provided on the substrate, a passivation layer provided on the circuit element layer, a planarization layer provided on the passivation layer, a first electrode provided on the planarization layer, a bank provided in the non-emission area on the first electrode, a light emitting layer provided on the first electrode and the bank, and a second electrode provided on the light emitting layer, wherein the planarization layer and the bank include a material that absorbs light.

### CROSS-REFERENCE TO RELATED APPLICATIONS

This application claims the priority of Korean Patent Application No. 10-2021-0188250 filed on Dec. 27, 2021, which is hereby incorporated by reference in its entirety.

### BACKGROUND

### Field of the Disclosure

The present disclosure relates to a display apparatus. Although the present disclosure is suitable for a wide scope of applications, it is particularly suitable for attenuating reflectance of external light and improving emission efficiency.

### Description of the Background

With the advancement of the information age, the demand for a display apparatus for displaying an image has increased in various forms. Therefore, various types of display apparatuses such as a liquid crystal display (LCD) apparatus, a plasma display panel (PDP) apparatus, and an electroluminescence display (ELD) apparatus have been used. The electroluminescence display (ELD) apparatus may include an organic light emitting display (OLED) apparatus and a quantum-dot light emitting display (QLED) apparatus.

Among the display apparatuses, the electroluminescence display apparatus is a self-light emitting type and has advantages in that a viewing angle and a contrast ratio are better than those of the liquid crystal display (LCD) apparatus. Also, since the electroluminescence display apparatus does not require a separate backlight, it is advantageous that the electroluminescence display apparatus is able to be thin and lightweight and has a low power consumption. Further, the electroluminescence display apparatus has advantages in that it may be driven at a direct current low voltage, has a fast response speed, and especially has a low manufacturing cost.

Meanwhile, when the electroluminescence display apparatus is provided in a top emission mode in which light is emitted to an upper direction, an anode made of five layers may be initiated to attenuate reflectance due to external light. For example, an anode may be formed in a stacked structure in which a transparent conductive layer made of a transparent conductive material such as indium-tin-oxide (ITO) or indium-zinc-oxide (IZO) and a metal layer made of metal such as molybdenum (Mo) and titanium (Ti) are alternately stacked. At this time, external light may be reflected by a plurality of metal layers in the anode and destructive interference can be generated, whereby the external light is extinguished and thus reflectance due to the external light may be attenuated.

However, when light emitted from a light emitting layer moves to a lower direction of the electroluminescence display apparatus, since the light emitted from the light emitting layer may be extinguished due to destructive interference in the anode, a problem occurs in that a change of a color difference and a change of reflectance occur due to a viewing angle.

The above information disclosed in this Background section is only for enhancement of understanding of the background of the described technology and therefore it may contain information that does not form prior art that is already known to a person of ordinary skill in the art.

### SUMMARY

Accordingly, the present disclosure has been formed in view of the above problems and is to provide an electroluminescence display apparatus in which reflectance of external light is attenuated and light efficiency is improved.

In addition, additional features of the present disclosure will be clearly understood by those skilled in the art from the following description of the present disclosure.

In accordance with an aspect of the present disclosure, the above and other features can be accomplished by the provision of a display apparatus comprising a substrate including a light emission area and a non-light emission area surrounding the light emission area, a circuit element layer provided on the substrate, a passivation layer provided on the circuit element layer, a planarization layer provided on the passivation layer, a first electrode provided on the planarization layer, a bank provided in the non-emission area on the first electrode, a light emitting layer provided on the first electrode and the bank, and a second electrode provided on the light emitting layer, wherein the planarization layer and the bank include a material that absorbs light.

In another aspect of the present disclosure, a display apparatus includes a substrate including a light emission area and a non-light emission area surrounding the light emission area, a circuit element layer disposed on the substrate, a passivation layer disposed on the circuit element layer, a light absorbing planarization layer disposed on the passivation layer and including an organic or inorganic material and a light absorbing material absorbing external light incident on the light absorbing layer and alleviating a step difference caused by the circuit element layer, a first electrode disposed on the planarization layer, a bank defining the light emission area and disposed in the non-emission area on the first electrode, a light emitting layer disposed on the first electrode and the bank, and a second electrode disposed on the light emitting layer.

It is to be understood that both the foregoing general description and the following detailed description are exemplary and explanatory and are intended to provide further explanation of the disclosure as claimed.

### BRIEF DESCRIPTION OF THE DRAWINGS

The above and other features and advantages of the present disclosure will be more clearly understood from the following detailed description taken in conjunction with the accompanying drawings, in which:

FIG. 1 is a schematic cross-sectional view illustrating an electroluminescence display apparatus according to an aspect of the present disclosure;

FIG. 2 is a schematic cross-sectional view illustrating an electroluminescence display apparatus according to another aspect of the present disclosure;

FIG. 3 is a cross-sectional view illustrating a path of external light in the electroluminescence display apparatus shown in FIG. 2; and

FIG. 4 is a graph illustrating a relation between an optical density and reflectance in the electroluminescence display apparatus shown in FIG. 2.

### DETAILED DESCRIPTION

Advantages and features of the present disclosure and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing aspects of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where ‘comprise’, ‘have’ and ‘include’ described in the present disclosure are used, another portion may be added unless ‘only˜’ is used. The terms of a singular form may include plural forms unless referred to the contrary.

In construing an element, the element is construed as including an error range although there is no explicit description.

In describing a position relationship, for example, when the position relationship is described as ‘upon˜’, ‘above˜’, ‘below˜’ and ‘next to˜’, one or more portions may be arranged between two other portions unless ‘just’ or ‘direct’ is used.

In describing a temporal relationship, for example, when the temporal order is described as ‘after˜’, ‘subsequent˜’, ‘next˜’ and ‘before˜’, a case which is not continuous may be included unless ‘just’ or ‘direct’ is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure may be partially or overall coupled to or combined with each other and may be variously inter-operated with each other and driven technically as those skilled in the art can sufficiently understand. The aspects of the present disclosure may be carried out independently from each other or may be carried out together in co-dependent relationship.

Hereinafter, various aspects of the present disclosure will be described with reference to the drawings.

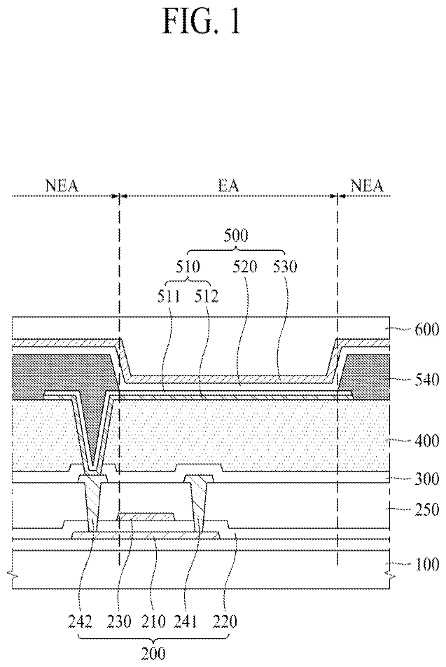

FIG. 1 is a schematic cross-sectional view illustrating an electroluminescence display apparatus according to an aspect of the present disclosure.

As shown in FIG. 1, the electroluminescence display apparatus according to an aspect of the present disclosure may include a substrate 100, a circuit element layer 200, a passivation layer 300, a planarization layer 400 (or a light absorbing planarization layer), a light emitting element 500, a bank 540, and an encapsulation layer 600.

The substrate 100 may be made of glass or plastic, but is not limited thereto, and may be made of a semiconductor material such as a silicon wafer. A plurality of subpixels are provided in the substrate 100, and only one subpixel is shown in FIG. 1. Each of the subpixels may include a light emission area EA in which light is emitted from a light emitting layer 520, and a non-light emission area NEA surrounding the light emission area EA.

The electroluminescence display apparatus according to an aspect of the present disclosure is provided in a top emission mode in which light is emitted to an upper direction, and thus an opaque material as well as a transparent material may be used as a material of the substrate 100.

The circuit element layer 200 may be formed on the substrate 100, and a circuit element that includes various signal lines, a plurality of thin film transistors and a capacitor may be provided in the circuit element layer 200. In FIG. 1 of the present disclosure, a driving thin film transistor TFT and an interlayer insulating layer 250 of the circuit element layer 200 are shown in detail.

The driving thin film transistor TFT may include an active layer 210, a gate insulating layer 220, a gate electrode 230, a source electrode 241 and a drain electrode 242.

The active layer 210 is provided on the substrate 100. The active layer 210 may be made of an oxide semiconductor such as In—Ga—Zn—O (IGZO), but is not limited thereto. The active layer 210 may be made of a silicon-based semiconductor. Also, the active layer 210 may include a channel area in which a channel is formed when the driving thin film transistor TFT is driven, and source and drain areas on both sides of the channel area. The source area refers to a portion of the active layer 210 connected to the source electrode 241, and the drain area refers to a portion of the active layer 210 connected to the drain electrode 242.

The gate insulating layer 220 may be provided on the active layer 210 to insulate the gate electrode 230 from the active layer 210. The gate insulating layer 220 may include a single layer of silicon nitride (SiNx) or silicon oxide (SiOx), or a multi-layer of silicon nitride (SiNx) and silicon oxide (SiOx). A contact hole for respectively connecting the source electrode 241 and the drain electrode 242 of the driving thin film transistor TFT to the source and drain areas of the active layer 210 of the driving thin film transistor TFT may be formed in the gate insulating layer 220.

The gate electrode 230 is provided on the gate insulating layer 220. The gate electrode 230 may be a single layer or multi-layer made of one of molybdenum (Mo), copper (Cu), titanium (Ti), aluminum (Al), chromium (Cr), gold (Au), nickel (Ni) and neodymium (Nd), or their alloy, but is not limited thereto.

The interlayer insulating layer 250 is provided on the gate insulating layer 220 and the gate electrode 230. The interlayer insulating layer 250 may be made of a single layer of silicon nitride (SiNx) or silicon oxide (SiOx), or a multi-layer of silicon nitride (SiNx) and silicon oxide (SiOx), but is not limited thereto.

The source electrode 241 and the drain electrode 242 are provided on the interlayer insulating layer 250 while facing each other. In addition, each of the source electrode 241 and the drain electrode 242 may be connected to the active layer 210 through a contact hole formed in the interlayer insulating layer 250. Each of the source electrode 241 and the drain electrode 242 may be formed of a single layer or multi-layer made of one of molybdenum (Mo), copper (Cu), titanium (Ti), aluminum (Al), chromium (Cr), gold (Au), nickel (Ni) and neodymium (Nd) or their alloy, but is not limited thereto.

The driving thin film transistor TFT of an aspect of the present disclosure is provided in a top gate structure in which the gate electrode 230 is formed on the active layer 210, but may be provided in a bottom gate structure in which the gate electrode 230 is formed below the active layer 210.

The passivation layer 300 is formed on the source electrode 241, the drain electrode 242 and the interlayer insulating layer 250. The passivation layer 300 may include a single layer of silicon nitride (SiNx) or silicon oxide (SiOx), or a multi-layer of silicon nitride (SiNx) and silicon oxide (SiOx), but is not limited thereto. The passivation layer 300 may be formed of an organic material such as an acrylic resin, an epoxy resin, a phenolic resin, a polyamide resin and a polyimide resin.

The planarization layer 400 may be provided on the passivation layer 300 to alleviate a step difference among various signal lines, the thin film transistors and the capacitor, which are provided in the circuit element layer 200. The planarization layer 400 may be formed of an organic layer such as an acrylic resin, an epoxy resin, a phenolic resin, a polyamide resin and a polyimide resin. Alternatively, the planarization layer 400 may be formed of an inorganic layer such as silicon nitride, aluminum nitride, zirconium nitride, titanium nitride, hafnium nitride, tantalum nitride, silicon oxide, aluminum oxide and titanium oxide. In addition, the planarization layer 400 may include a black dye that can absorb light, thereby absorbing most of the external light incident on the planarization layer 400.

A first electrode 510 may be provided on the planarization layer 400, and may serve as an anode of an organic light emitting display apparatus. The first electrode 510 is connected to the drain electrode 242 provided in the circuit element layer 200.

The first electrode 510 may include a transparent conductive layer 511 and a low-reflective metal layer 512.

The low-reflective metal layer 512 is provided on the planarization layer 400. The low-reflective metal layer 512 may be formed of a single layer or multi-layer made of a metal material such as molybdenum (Mo) and titanium (Ti), or their alloy.

The low-reflective metal layer 512 may reflect a portion of the light, and may transmit the other portion of the light. In addition, the amount of the light reflected from the low-reflective metal layer 512 may be smaller than the amount of the light transmitted from the low-reflective metal layer 512. In detail, the light reflected from the low-reflective metal layer 512 moves to an upper direction of the display apparatus to increase the amount of light emitted from the light emission area EA, and the light transmitted from the low-reflective metal layer 512 may be incident on the planarization layer 400 provided below the low-reflective metal layer 512 and then absorbed into the planarization layer 400. Therefore, the display apparatus can prevent decrease in light efficiency while attenuating reflectance due to the external light.

The transparent conductive layer 511 may be provided on the low-reflective metal layer 512. In addition, the transparent conductive layer 511 may be made of a transparent conductive material to transmit the light reflected from the low-reflective metal layer 512 toward the upper direction of the display apparatus. For example, the transparent conductive layer 511 may be formed of a single layer or multi-layer made of a transparent conductive material such as indium tin oxide (ITO) and indium zinc oxide (IZO).

Although not shown in FIG. 1, the transparent conductive layer 511 may be additionally provided between the low-reflective metal layer 512 and the planarization layer 400 to improve adhesion between the low-reflective metal layer 512 and the planarization layer 400.

The bank 540 is formed on the first electrode 510 to define a light emission area EA and a non-light emission area NEA. That is, an area in which the bank 540 is not formed may be the light emission area EA, and an area in which the bank 540 is formed may be the non-light emission area NEA.

The bank 540 may be formed of an organic layer such as an acrylic resin, an epoxy resin, a phenolic resin, a polyamide resin and a polyimide resin. Alternatively, the bank 540 may be formed of an inorganic layer such as silicon nitride, aluminum nitride, zirconium nitride, titanium nitride, hafnium nitride, tantalum nitride, silicon oxide, aluminum oxide, and titanium oxide. In addition, the bank 540 may include a black dye that can absorb the light incident from the outside of the display apparatus, and may be made of the same material as that of the planarization layer 400.

The light emitting layer 520 is formed on the first electrode 510. The light emitting layer 520 may be formed on the bank 540. That is, the light emitting layer 520 may be formed in the light emission area EA and the non-light emission area NEA.

The light emitting layer 520 may include a hole transporting layer, an organic light emitting layer, and an electron transporting layer. In this case, when a voltage is applied to the first electrode 510 and a second electrode 530, holes and electrons move to the light emitting layer through the hole transporting layer and the electron transporting layer, respectively and are combined with each other in the light emitting layer to emit light.

The light emitting layer 520 may be provided to emit white light. To this end, the light emitting layer 520 may include a plurality of stacks that emit light of different colors.

The second electrode 530 is formed on the light emitting layer 520. The second electrode 530 may serve as a cathode of the organic light emitting display apparatus. In the same manner as the light emitting layer 520, the second electrode 530 is also formed in the light emission area EA and the non-light emission area NEA.

In the electroluminescence display apparatus according to an aspect of the present disclosure, the second electrode 530 is made of a transparent conductive material such as indium tin oxide (ITO) and indium zinc oxide (IZO) so as to transmit the light emitted from the light emitting layer 520 toward the upper direction.

The encapsulation layer 600 is formed on the second electrode 530 to prevent external water from being permeated into the light emitting layer 520. The encapsulation layer 600 may be made of an inorganic insulator, or may be made of a structure in which an inorganic insulator and an organic insulator are alternately stacked, but is not limited thereto. Although not shown, a color filter for converting a color of the light emitted from the light emitting layer 520 may be provided on the encapsulation layer 600, and a protective film may be additionally provided on the color filter.

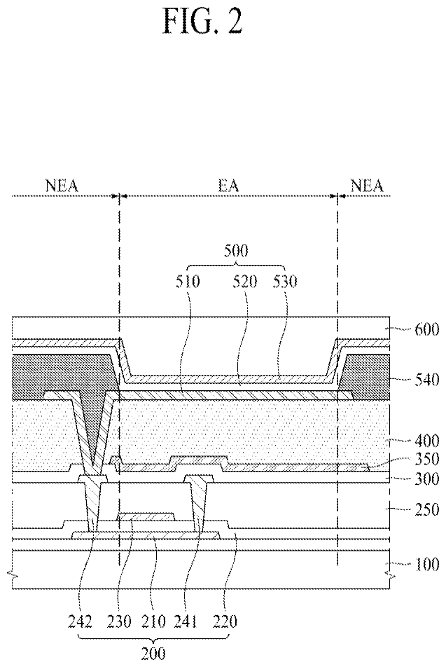

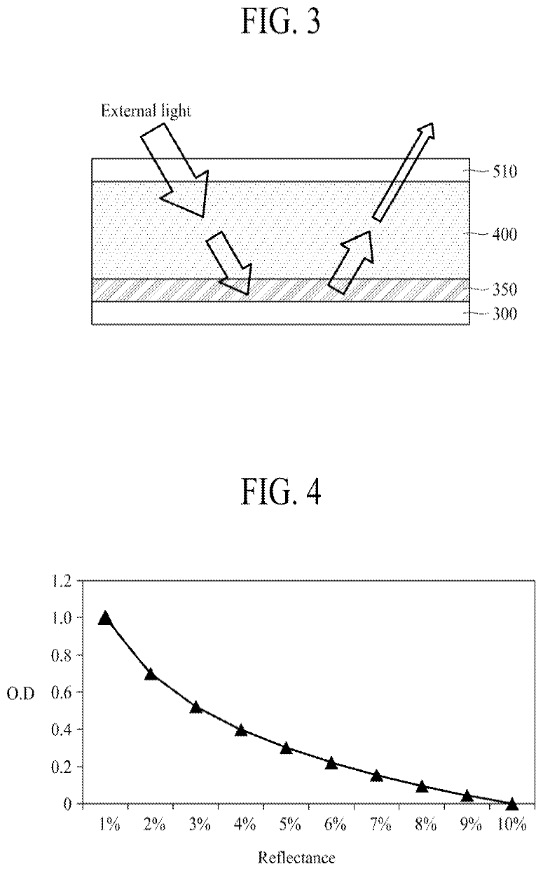

FIG. 2 is a schematic cross-sectional view illustrating an electroluminescence display apparatus according to another aspect of the present disclosure, and FIG. 3 is a cross-sectional view illustrating a path of external light in the electroluminescence display apparatus shown in FIG. 2.

As shown in FIG. 2, the display apparatus according to FIG. 2 has a structure in which the planarization layer 400 and the first electrode 510 are modified from the display apparatus of FIG. 1. In addition, the display apparatus according to FIG. 2 further includes a high-reflective metal layer 350. Hereinafter, the description will be mostly based on the differences from FIG. 1.

The high-reflective metal layer 350 is provided on the passivation layer 300, and may reflect light incident from the outside. Also, the high-reflective metal layer 350 may be formed of a single layer or multi-layer made of a metal material such as aluminum (Al) and silver (Ag) or their alloy. In addition, the high-reflective metal layer 350 may be formed on the light emission area EA, and both ends of the high-reflective metal layer 350 may be extended from the light emission area EA and then formed in the non-light emission area NEA.

Although not shown in FIG. 2, a transparent conductive layer may be additionally provided on an upper portion or a lower portion of the high-reflective metal layer 350. In detail, the transparent conductive layer may be additionally provided between the high-reflective metal layer 350 and the planarization layer 400 to increase adhesion between the high-reflective metal layer 350 and the planarization layer 400. Alternatively, a transparent conductive layer may be additionally provided between the high-reflective metal layer 350 and the passivation layer 300 to increase adhesion between the high-reflective metal layer 350 and the passivation layer 300. At this time, since the transparent conductive layer is made of a transparent conductive material such as indium tin oxide (ITO) and indium zinc oxide (IZO), the transparent conductive layer may transmit light reflected from the high-reflective metal layer 350.

The planarization layer 400 may be provided on the passivation layer 300 and the high-reflective metal layer 350 to alleviate a step difference among various signal lines, thin film transistors and capacitor, which are provided in the circuit element layer 200. The planarization layer 400 may be a single layer or multi-layer made of an organic layer or an inorganic layer.

The planarization layer 400 may be formed of a material having a low optical density value. That is, the optical density of the material constituting the planarization layer 400 may be lower than that of the material constituting the bank 540. As the value of the optical density becomes lower, the amount of incident light absorbed into the material is reduced, whereas the amount of incident light transmitting the material is increased. Therefore, a portion of the external light incident on the planarization layer 400 may be absorbed by the planarization layer 400, and the external light that is not absorbed by the planarization layer 400 may transmit the planarization layer 400.

The first electrode 510 may be provided on the planarization layer 400, and may serve as an anode of the display apparatus. The first electrode 510 is connected to the drain electrode 242 provided in the circuit element layer 200. In addition, the first electrode 510 may be made of a transparent conductive material to transmit the light reflected from the high-reflective metal layer 350 toward the upper direction of the display apparatus. For example, the first electrode 510 may be formed of a single layer or multi-layer made of a transparent conductive material such as indium tin oxide (ITO) or indium zinc oxide (IZO).

The path of the external light according to the second aspect of the present disclosure will be described with reference to FIG. 3.

First, the external light may be incident on the planarization layer 400. Also, a portion of the light emitted from the light emitting layer 520 may be directed toward the lower direction of the display apparatus, and may be incident on the planarization layer 400.

The planarization layer 400 is made of a material having a relatively low optical density value. As the value of the optical density becomes lower, the amount of incident light absorbed into the material is reduced, whereas the amount of incident light transmitting the material is increased. Therefore, a portion of the external light incident on the planarization layer 400 may be absorbed by the planarization layer 400, and the external light that is not absorbed by the planarization layer 400 may transmit the planarization layer 400.

A portion of the light incident on the planarization layer 400 may be incident on the high-reflective metal layer 350 by transmitting the planarization layer 400. The high-reflective metal layer 350 reflects most of the incident light, and the reflected light may move toward the upper direction of the display apparatus.

The light reflected from the high reflection metal layer 350 may be again incident on the planarization layer 400. As described above, a portion of the light incident on the planarization layer 400 may be absorbed by the planarization layer 400, and the light that is not absorbed by the planarization layer 400 may transmit the planarization layer 400.

Finally, the light that has transmitted the planarization layer 400 may be emitted toward the upper direction of the display apparatus by transmitting the first electrode 510.

Therefore, since the planarization layer 400 of FIG. 1 is made of a black dye but the planarization layer 400 of the second aspect is made of a material having a low optical density, the amount of light absorbed in the planarization layer 400 of FIG. 2 may be reduced as compared with FIG. 1. In addition, in FIG. 2, the high-reflective metal layer 350 is provided, so that most of the light, which has transmitted the planarization layer 400, may be emitted toward the upper direction of the display apparatus. Therefore, reflectance of the external incident light may be attenuated and light efficiency of the display apparatus may be further improved as compared with the first aspect.

FIG. 4 is a graph illustrating a relation between an optical density OD and reflectance of the display apparatus in the electroluminescence display apparatus shown in FIG. 2. That is, in the structure of FIG. 2, a reflectance value of the display apparatus according to the optical density OD of the planarization layer 400 is shown. In this case, as described in FIG. 3, reflectance of the display apparatus refers to reflectance of external light finally emitted toward the upper direction of the display apparatus after the external light is absorbed or reflected by the planarization layer 400 and the high-reflective metal layer 350.

The light emitted from the display apparatus includes light emitted directly from the light emitting layer 520 and light reflected from the inside of the display apparatus. Therefore, when the reflectance value of the display apparatus is very low, since the amount of the light reflected inside the display apparatus is also reduced, light efficiency of the display apparatus may be reduced. On the other hand, when the reflectance value is very high, visibility of the display apparatus may be reduced.

Referring to FIG. 4, it is noted that the reflectance value is increased as the value of the optical density OD becomes low. Therefore, the value of the optical density OD of the planarization layer 400 may be relatively low. In detail, since reflectance that may improve light efficiency of the display apparatus is typically in the range of 5% to 7%, the optical density OD of the planarization layer 400 may be within the range of 0.15 to 0.3.

According to the present disclosure, the following advantageous effects may be obtained.

According to the present disclosure, the planarization layer that includes a material absorbing light is formed, so that reflectance of the external light may be attenuated and light efficiency of the display apparatus may be improved.

It will be apparent to those skilled in the art that the present disclosure described above is not limited by the above-described aspects and the accompanying drawings and that various substitutions, modifications and variations may be formed in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display apparatus comprising:
a substrate including a light emission area and a non-light emission area surrounding the light emission area;
a circuit element layer provided on the substrate;
a passivation layer provided on the circuit element layer;
a planarization layer provided on the passivation layer;
a first electrode provided on the planarization layer;
a bank provided in the non-emission area on the first electrode;
a light emitting layer provided on the first electrode and the bank; and
a second electrode provided on the light emitting layer,
wherein the planarization layer and the bank include a material absorbing light incident on the planarization layer and the bank.

2. The display apparatus of claim 1, wherein the first electrode includes a low-reflective metal layer disposed on the planarization layer and a transparent conductive layer provided on the low-reflective metal layer.

3. The display apparatus of claim 2, wherein the low-reflective metal layer includes molybdenum (Mo) or titanium (Ti), and the transparent conductive layer includes indium tin oxide (ITO) or indium zinc oxide (IZO).

4. The display apparatus of claim 2, further comprising a transparent conductive layer between the low-reflective metal layer and the planarization layer.

5. The display apparatus of claim 1, wherein the planarization layer and the bank include an organic or inorganic material containing a black dye.

6. The display apparatus of claim 1, further comprising a high-reflective metal layer between the passivation layer and the planarization layer.

7. The display apparatus of claim 6, wherein the high-reflective metal layer is located in the light emission area.

8. The display apparatus of claim 7, wherein both ends of the high-reflective metal layer are extended from the light emission area to the non-light emission area.

9. The display apparatus of claim 6, wherein the high-reflective metal layer includes aluminum (Al) or silver (Ag).

10. The display apparatus of claim 6, further comprising a transparent conductive layer provided on an upper or lower portion of the high-reflective metal layer.

11. The display apparatus of claim 6, wherein the planarization layer has an optical density lower than the bank.

12. The display apparatus of claim 11, wherein the optical density of the planarization layer ranges from 0.15 to 0.3.

13. A display apparatus comprising:
a substrate including a light emission area and a non-light emission area surrounding the light emission area;
a circuit element layer disposed on the substrate;
a passivation layer disposed on the circuit element layer;
a light absorbing planarization layer disposed on the passivation layer and including an organic or inorganic material and a light absorbing material absorbing external light incident on the light absorbing layer and alleviating a step difference caused by the circuit element layer;
a first electrode disposed on the light absorbing planarization layer;
a bank defining the light emission area and disposed in the non-emission area on the first electrode;
a light emitting layer disposed on the first electrode and the bank; and
a second electrode disposed on the light emitting layer.

14. The display apparatus of claim 13, wherein the bank includes an organic or inorganic material and a light absorbing material to absorb the external light incident on the bank.

15. The display apparatus of claim 13, wherein the light absorbing material includes a black dye.

16. The display apparatus of claim 13, further comprising a high-reflective metal layer disposed between the passivation layer and the light absorbing planarization layer.

17. The display apparatus of claim 16, wherein the high-reflective metal layer is located in the light emission area and both ends of the high-reflective metal layer are extended from the light emission area to the non-light emission area.

18. The display apparatus of claim 16, wherein the high-reflective metal layer includes aluminum or silver.

19. The display apparatus of claim 16, further comprising a transparent conductive layer disposed on an upper or lower side of the high-reflective metal layer.

20. The display apparatus of claim 16, wherein the light absorbing planarization layer has an optical density lower than the bank.
